(19) United States
(12) Patent Application Publication
(10) Pub. No.: US 2006/0099341 A1
(43) Pub. Date: May 11, 2006

(54) High frequency plasma jet source and method for irradiating a surface

(76) Inventor: Rudolf Beckmann, Hammersbach (DE)

Correspondence Address: FULBRIGHT & JAWORSKI, LLP, 666 FIFTH AVE, NEW YORK, NY, 10103-3198, US

(21) Appl. No.: 10/552,677

(22) PCT Filed: Apr. 8, 2004
(86) PCT No.: PCT/EP04/03796

§ 371 Date: Nov. 21, 2005

(30) Foreign Application Priority Data
Apr. 11, 2003 (DE) 10317027.8

(51) Int. Cl. C23C 16/00

(52) U.S. Cl. 427/248.1; 118/723 R

(57) ABSTRACT

The invention relates to a high-frequency plasma beam source with a plasma chamber for a plasma, electrical means for applying an electrical voltage to the high-frequency plasma beam source to ignite and maintain the plasma, extraction means for extracting a plasma beam (I) from the plasma chamber as well as an exit opening, which is separated from the vacuum chamber by an extraction grid. The plasma beam (I) exits with a substantially divergent radiation characteristic from the high-frequency plasma beam source. The invention furthermore relates to a method for the irradiation of a surface with a plasma beam (I) of a high-frequency plasma beam source, the plasma beam (I) being divergent.

The invention relates to a high-frequency plasma source as well as a method for the irradiation of a surface with a plasma beam, according to the introductory part of the independent claims.

In methods for vacuum coating substrates, so-called high-frequency plasma beam sources are often used. A plasma contains electrons and positive ions as charged particles in addition to neutral atoms and/or molecules. The charged particles are accelerated by electrical and/or magnetic fields and used, for example, for removing a surface or for the input of reactive components such as oxygen into a freshly growing coating and other such purposes. Also known are ion-supported methods wherein material from a source, typically an evaporator source, is evaporated and precipitates onto a substrate. The material growing on the substrate is treated with a reactive component from a plasma and thus forms, for example, an oxide coating. Such processes are common, for example, in the production of transparent coatings for optical applications. At the same time it is also of considerable importance how uniformly the plasma beam strikes the coating, since the optical properties of such coatings vary greatly, as a rule, with the oxygen content.

In the production of thin coatings in microelectronics or for optical applications, the production of very uniform coating thicknesses and coating properties is sought, such as for example the refractive index of the deposited coatings. In industrial applications, large areas are coated, and/or many substrates together, which increases the problem of uniform coating thicknesses. Especially in the case of optical coatings, variations of the coating thickness over an area or within the substrates of a coating that amount in any case to a few percent are considered to be tolerable.

In European patent EP 349 556 B1, a high-frequency plasma beam source is disclosed for the assurance of a very uniform large-area bombardment of surfaces with atom or molecule beams of great parallelism. The aperture of the high-frequency plasma beam source is provided with an extraction grid which has a very small mesh width so as not to interfere with the plasma. The extraction grid is designed as a high-frequency guiding electrode in the form of an appropriately configured wire mesh in the form of wires running parallel. Between the plasma and the extraction grid an ion-accelerating potential difference is produced which makes possible a neutral plasma beam which is completely homogeneous across the direction of the beam and has no modulation texture. In order always to keep the surface of the extraction grid flat and avoid any unwanted influence of the plasma beam due to deformation of the extraction grid, the mounting of the extraction grid of the known high-frequency plasma beam source is provided with a retightening device. It is common practice to increase the diameter of the high-frequency plasma beam source to permit broader irradiation. This, however, increases the costs and also quickly collides with design limits.

In vapor depositing processes a large number of substrates are uniformly coated by arranging the substrates on a spherical cap. Thus an especially large area is uniformly coated.

Whenever the known high-frequency plasma beam source is used for large-area depositing of coatings on substrates which are arranged on such a cap or other curved surfaces, it is found also that, even with an increase of the diameter of the high-frequency plasma beam source, impairments of the uniformity of the deposited coating thickness and coating properties have to be accepted. As a consequence a large-area irradiation cannot be accomplished with the desired quality requirements.

The problem of the present invention is the creation of a high-frequency plasma beam source, of a vacuum chamber equipped with such a high-frequency plasma beam source, and of a method for the irradiation of a surface with a plasma beam, which permit a high-quality irradiation of large areas of surfaces.

This problem is solved according to the invention by the characteristics of the independent claims.

According to a preferred aspect of the invention, contrary to the teaching of the state of the art, a divergent neutral plasma beam is produced.

It is an advantage of the invention that, by the formation according to the invention of the high-frequency plasma beam source, it succeeds in depositing uniform, large-area coatings even on substrates which are arranged on a dome, or in cleaning large surfaces.

A further aspect of the invention is a high-frequency plasma beam source, especially one with a plasma beam of great parallelism, which for the improved irradiation of substrates arrayed on a dome has at least one diaphragm arranged outside of a plasma space, by which inhomogenous areas of plasma beam density on the dome or substrates are avoided. Likewise, the exit aperture of the plasma space can be covered with diaphragms.

The invention is further described below with the aid of drawings in which additional features, details and advantages of the invention will be seen independently of the summation given in the claims.

The following are schematic representations:

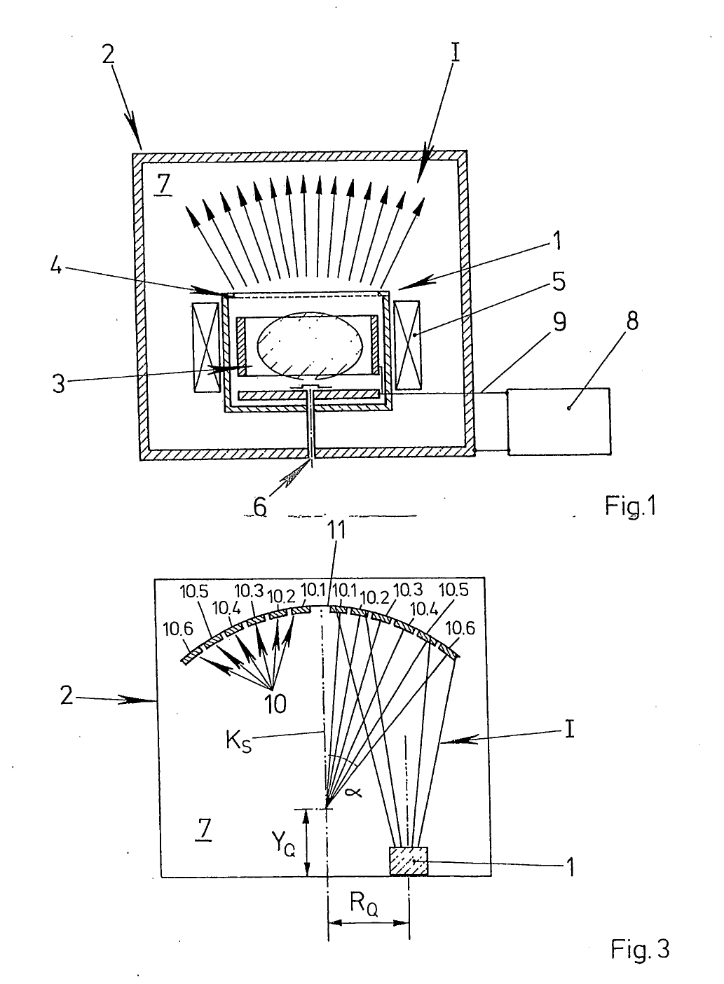

FIG. 1 A coating chamber with a preferred high-frequency plasma beam source,

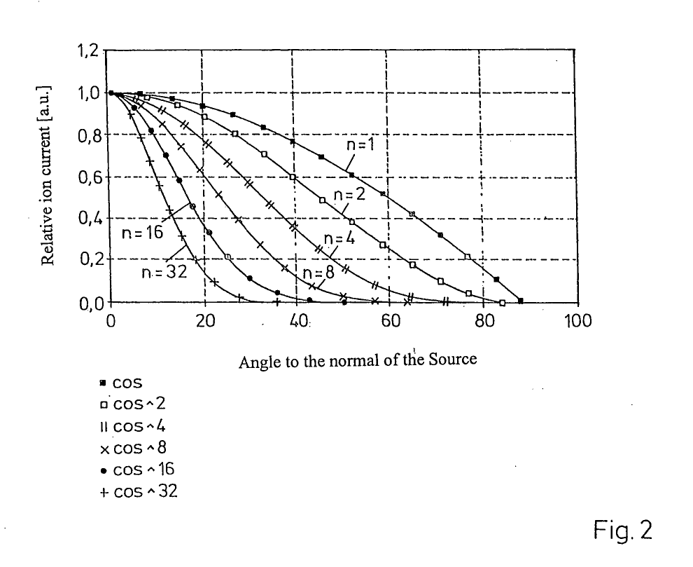

FIG. 2 Distribution curves of a cosⁿ beam characteristic,

FIG. 3 The geometrical proportions in the coating chamber of FIG. 1, substrates being arranged on a dome,

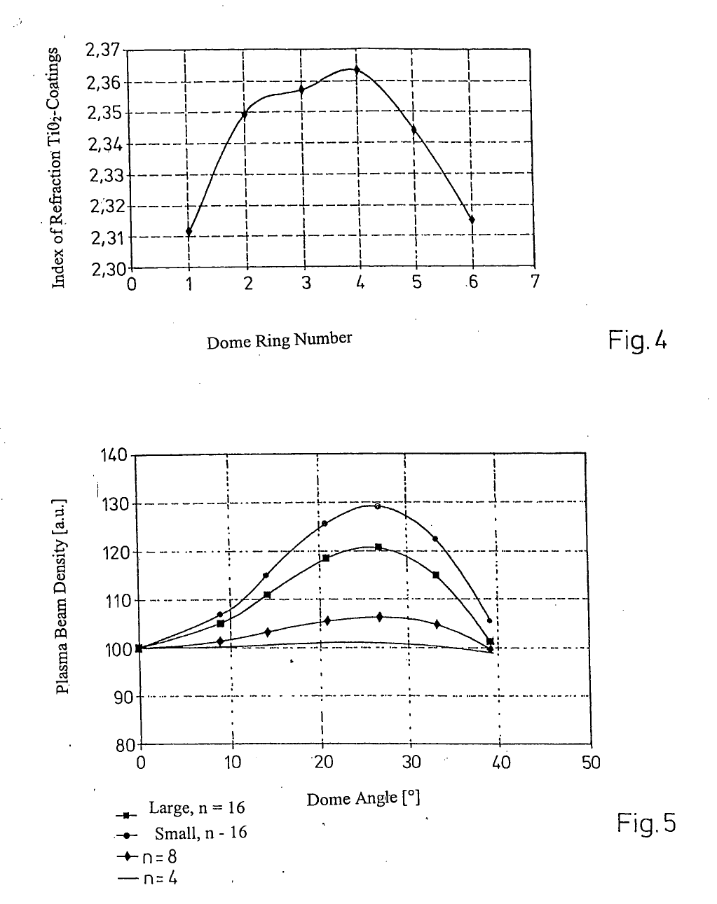

FIG. 4 Distribution of a dioptric power of TiO₂ coatings on a dome,

FIG. 5 The influence of the size of the exit aperture of a plasma beam source and of the beam divergence on the distribution of the plasma beam density on a dome,

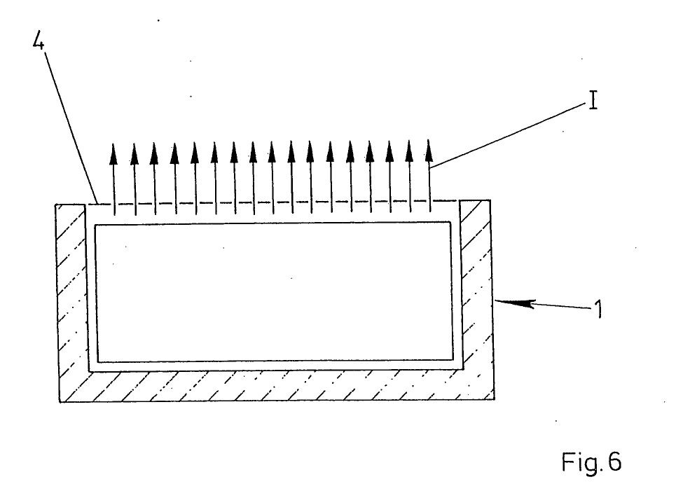

FIG. 6 A high-frequency plasma beam source of the state of the art,

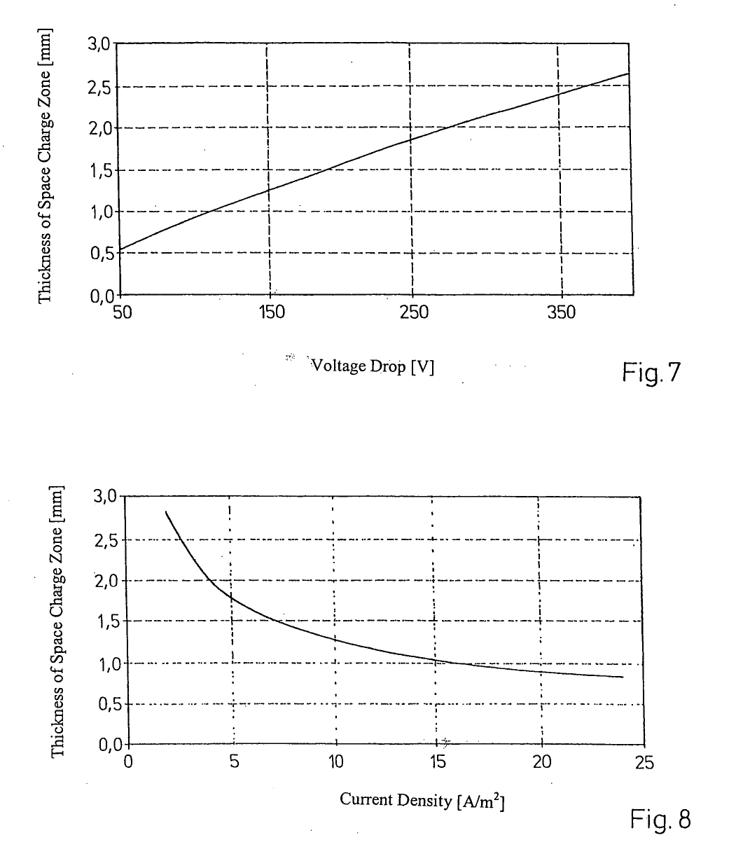

FIG. 7 The thickness of the space charge zone depending on the applied extraction voltage,

FIG. 8 The thickness of the space charge zone depending on the current density in the case of a fixed extraction voltage,

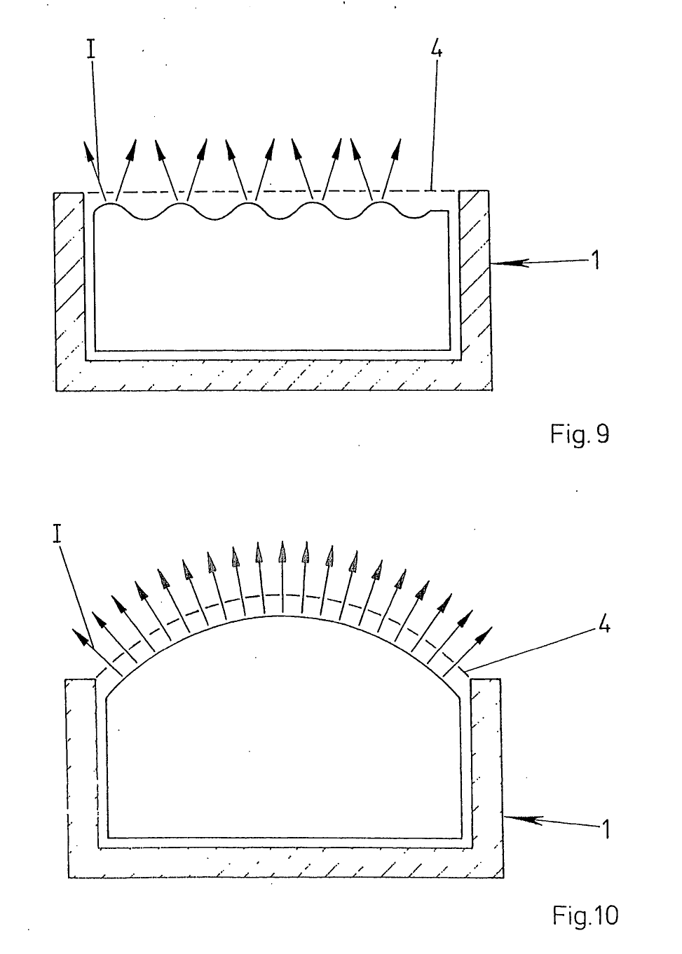

FIG. 9 A preferred configuration of the extraction grid, and

FIG. 10 Another preferred configuration of the extraction grid.

FIG. 1 shows schematically a high-frequency plasma source 1, hereinafter called “Hf plasma beam source”, with a divergent neutral plasma beam I. The Hf plasma beam source 1 is of pot-like construction and is disposed in a part of a vacuum chamber designed as a coating chamber 7, which is surrounded by a housing 2. Details of the coating chamber, such as conventional vacuum pumps, gas supply substrate holders, analytic equipment etc., are not represented. The Hf plasma source 1 has a plasma chamber 3 in which a plasma is ignited, by high-frequency radiation, for example. For the ignition and maintenance of the plasma, electrical means 8 and 9 are provided, such as a high-frequency transmitter 8 and electrical connections 9. Furthermore, at least one magnet 5 can be provided, which is used conventionally to fire the plasma into the plasma chamber 3. To supply gas to the Hf plasma beam source 1 a feeder 6 is provided. For the extraction of a neutral plasma beam from the plasma in the plasma chamber 3, an extraction grid 4 of preferably high transmissivity is arranged in an area of an outlet aperture. The area of the surface of the extraction grid 4 that is available for transmission, especially that which is not concealed, is called the source factor. In general the source factor is established by the size of the exit opening. Such a source, although one having a flat extraction grid and a strongly directed plasma beam, is already disclosed in EP 349 556 B1. Preferred is a source operating on the ECWR principle with a plasma of relatively high density.

A divergent plasma beam 1 according to the invention is produced preferably by a specific interaction between the plasma and the extraction grid 4. The extraction grid 4 is constructed such that the plasma beam 1 has a substantially divergent characteristic. Details of such extraction grids are shown in greater detail in FIGS. 9 and 10.

A divergent plasma beam is to be understood as a plasma beam which markedly radiates in at least one direction perpendicular to the main direction of radiation, i.e., the direction of greatest plasma beam density. Usually the main direction of radiation is called a “source normal.” A beam divergence can be described approximately by an exponent n of a cosine distribution. The exponent n of the cosine distribution is a measure of the beam divergence. The greater n is, the more divergent is the plasma beam. A detailed treatment of such distribution function is to be found in G. Deppisch: Coating Thickness Uniformity of Vapor-deposited Coatings in Theory and Practice, Vakuum Technik, Vol. 30, No. 3, 1981. FIG. 2 shows curves of cosⁿ distributions of a relative ion current of a plasma beam as a function of the angle of the radiation to the source normal for various values of n. This distribution is a mathematically calculated magnitude which indicates how greatly the ion beam density depends on the angle. In the case of a greatly divergent beam (n=1) at an angle of, e.g., 40 to the source normal, 78% is reached of the value which is emitted in the direction of the source normal. At n=8, however, only 13% is emitted at this angle. In the case of a plasma beam with n=16 or n=36, virtually no plasma beam is present at an angle of 40°. In FIG. 3 the geometric ratios in a vacuum chamber 7 constructed as a coating chamber are represented. In the coating chamber 7 a plurality of substrates 10.1, 10.2, 10.3, 10.4, 10.5 and 10.6 are arranged on a substantially spherical dome 11. The dome 11 has the shape of a section of a ball cup. The substrates 10.1, 10.2, 10.3, 10.4, 10.5 and 10.6 are each placed on circles on the dome 11, i.e., each reference number designates a plurality of substrates which are arranged on the particular circle on the dome 11. The vertical broken lines correspond to the direction of a source normal or of one parallel thereto. The innermost circle with the substrates 10.1 corresponds to a dome angle α of, for example, 9°, the next circle with the substrates 10.2 an angle of α=14°, the next circle with substrates 10.3 an angle of α=21°, the next circle with the substrates 10.4 an angle of α=27°, the next with an angle of α=33° and the outermost circle with an angle of α=39°.

The dome 11 can rotate during the coating in order to obtain a better uniformity of the coating thickness. The Hf plasma beam source 1 is in the present case applied offset from the center of symmetry, R_{Q} representing the radial distance of the source from the axis of symmetry K_{S} of the dome 11. In addition to R_{Q}, the direction of especially the source normals and/or the distance Y_{Q} can be varied in order deliberately to influence the intensity of the plasma beam on the substrates 10.1, 10.2, 10.3, 10.4, 10.5 and 10.6. If preferred an additional material source can also be provided in the coating chamber 7, especially an evaporation source. Also, the source can be tilted at an angle beta against the direction of the axis of symmetry. In other developments of the invention the surface on which the substrates are arranged can have a different, preferably curved shape.

Usually, in order to achieve a uniform, broad-area illumination of the dome 11, an Hf plasma beam source 1 is selected which has an outlet opening as large as possible and a directed plasma beam. It is true that the practical results of coating experiments as well as simulated computations for a configuration of apparatus of this kind show that any enlargement of the outlet opening achieves only conditionally a sufficient uniformity of the thickness of the coatings deposited on the substrates. However, an improvement of the coating quality, especially of the uniformity of the coating thickness, is possible according to the invention through the use of a divergent plasma beam I.

FIG. 4 shows refractive index distributions of TiO₂ coatings on a substantially spherical dome. In this case titanium dioxide TiO₂ was deposited with an Hf plasma beam source with an outlet aperture of 16≦n≦32 and larger in a coating chamber 7 as represented in FIG. 1 and FIG. 2. TiO₂ is transparent and has a refractive index which depends on the intensity of the plasma beam used. The outlet opening of the Hf plasma beam source has an area of 18.750 mm². In the case of a uniform illumination of the dome 11 the optical refractive index is around 2.2, and in the case of very high densities of the plasma beam it reaches a value of up to 2.4. The results of measurement in FIG. 4 show that, on the basis of the variation of the plasma beam density the index of refraction in a coating on positions 1 and 6 is around 30% lower than at positions 2 to 5, the positions corresponding to the said circles corresponding to 10.1, . . . on dome 11 in FIG. 2 and the associated angles on the dome 11.

FIG. 5 shows a simulated calculation on the influence of the exit opening of an Hf plasma beam source and of the beam divergence on the distribution of the plasma beam densities on a dome. In the case of a Hf plasma beam source with n=16 and a relatively small exit opening (only 1/10th of the area as in FIG. 4), the plasma beam density is most greatly dependent upon the dome angle (topmost curve). In an Hf plasma beam source of an equal divergence of n=16, but a larger exit opening, the dependence on the angle is slightly less. The curves of n=8 and n=4 are likewise computed with the small exit opening. It can clearly be seen that, with increasing divergence, i.e., with decreasing exponent n, the plasma beam density varies with the dome angle. Thus the homogeneity of the plasma beam across the dome increases.

A divergent plasma beam I permits a uniform large-area irradiation of the dome 11. In the case of the depositing of material on a substrate and/or an irradiation of the substrate with a plasma beam, e.g., for the modification of the substrate, a divergent plasma beam leads to substantially more uniform results than a conventional method with an Hf plasma source having a larger outlet opening and a plasma beam of great parallelism. In the case of a planar surface and a divergent plasma beam, less uniformity of the irradiation is to be expected, but it will still be sufficient for many applications, such as for example the cleaning of surfaces.

In the method of the invention for irradiating a surface, a plasma beam I of a high-frequency plasma beam source with a great beam divergence, preferably with a divergence of no more than n=16, especially n=4 and n=10, is used, n being an exponent of the cosine distribution function cosⁿ which describes the beam convergence. A plasma beam 1 with this characteristic permits, for example, a plasma beam density of great uniformity on the substrates 10.1, . . . on the dome 11 and modifies a coating and/or feeds components such as oxygen.

It is to be understood that the invention is not limited to Hf plasma beam sources whose divergent beam characteristic can be described by a cosine distribution function, but includes any suitable designed divergent beam characteristic.

A desired divergence of a divergent beam can be achieved by appropriately designing the HF plasma beam source 1. Preferably, the configurations of the extraction grid 4 that are known in the state of the art are modified in the area of the exit opening of the Hf plasma beam source 1. Three possibilities are preferred. The extraction grid 4 has meshes with a great mesh width or it is not planar but made concave or convex toward the plasma. Also, the extraction grid 4 can have a concave or convex shape as well as meshes with a great mesh width. The extraction grid 4 consists preferably of a tungsten mesh with a wire thickness of about 0.02-3 mm, preferably 0.1-1 mm. It is preferred if at least a portion of the area of the extraction grid is a section from the circumferential surface of a cylinder-like, especially a cylindrical body. For example, the extraction grid can have a rectangular base surface corresponding to an exit opening of the Hf plasma beam source 1 and shaped accordingly. In the case of a cylindrical body the long axis of the cylinder can be arranged parallel to one of the sides of the rectangle. By the curvature of the cylinder's mantle surface a concave or convex shape with respect to the plasma is created.

For comparison, FIG. 6 shows schematically an Hf plasma beam source with a planar extraction grid 4 in the area of an exit opening, and a plasma beam 1 of high parallelism according to the state of the art. The marginal layer of the plasma is substantially planar at the extraction grid 4. According to general doctrine, as known for example from EP 349 556 B1, the extraction grid 4 is made with such a fine mesh that the plasma is not affected by it. The mesh width therefore made smaller than the thickness of the space charge zone between the extraction grid 4 and the plasma.

The thickness d of the space charge zone can be taken from textbooks. Accordingly, the thickness d depends on the current density j and the voltage drop U between the plasma margin and the extraction grid 4:

$$d = \sqrt{\frac{4 {ɛ}_{0}}{9 \cdot j}} \cdot \sqrt[4]{\frac{2 \cdot e}{{m}_{ion}}} \cdot {U}^{\frac{3}{4}}$$

wherein

ε₀: dielectric constant of the vacuum

e: elemental charge

mᵢₒₙ: mass of the participating ions

U: voltage drop between the margin of the plasma and the extraction grid 4

(corresponds to the extraction voltage)

To determine the mesh width, increased according to the invention, of the extraction grid, the procedure is as follows.

For an ion current of 10 A/m², which represents a common value for the operation of such coating apparatus, the thickness d of the space charge zone was calculated in the case of a Hf plasma beam source with an exit opening of 0.1 m². This is represented in FIG. 7. The thickness d of the space charge coating accordingly increases with increasing voltage drop and varies between 0.5 mm to o 2.5 mm for a voltage drop between about 50 and about 370 volts. The thickness d in a preferred voltage range between 50 and 200 volts is definitely less than 2 mm.

If one considers how the thickness d of the space charge zone depends on the ion current density for a fixed extraction voltage of 150 volts, for example, the result is the curve shown in FIG. 8. The thickness of the space charge coating d decreases as a fixed extraction voltage with increasing current density. In a preferred range between 4 A/m² and 25 A/m² the thickness d of the space charge zone is less than 2 mm.

FIG. 9 shows schematically a plasma beam source 1 according to the invention with a preferred configuration of an extraction grid 4 with meshes with an increased mesh width. If the mesh width is greater than the thickness d of the space charge zone, the plasma margin layer deforms in this area, as is indicated by the undulant curve below the extraction grid 4. This leads to an increased divergence of the plasma beam 1. Reasonably the mesh width should still be small enough to prevent the plasma from markedly escaping through the exit opening. The mesh width amounts preferably to no more than 30 mm, and especially preferably to 20 mm at most, especially if the thickness of the space charge zone is in a range between 0.5 and 2.5 mm.

FIG. 10 shows schematically another preferred configuration of an extraction grid 4, which is not planar but concave as seen from the plasma chamber 3. As a result a curved plasma margin coating forms, and the issuing plasma beam 1 shows a divergent radiation characteristic. Here the mesh width of the extraction grid 4 can also be relatively small, and especially less than the thickness of the space charge zone. The extraction grid 4 can also be made convex.

In another embodiment the extraction grid 4 can be made non-uniform over at least a portion of its surface. For this purpose a mesh width can be varied, for example, so that toward the margin a lesser mesh width is provided. Also, for the modulation of the plasma jet outside of the plasma chamber 3, one or more masks can be provided. Also, the outlet opening can be covered in areas with masks and thus areas of the surface that are not uniformly irradiated can be masked off. The masks can additionally by provided with an electrical potential in order to additionally modulate the plasma stream.

In an alternative embodiment of the invention an Hf plasma stream source known in itself from EP 349 556 B1 can be used with a planar extraction grid for the irradiation of substrates arranged on a dome, in which case, however, at least one mask is arranged in an area outside of the plasma chamber of the source. This mask modulates the plasma beam such that the otherwise irregularly irradiated areas on the dome are excepted from the radiation. This can also be done by masking off portions of the outlet opening, The shape of the masks used is preferably determined empirically with the aid of the radiation results obtained. Additionally, provision is made for the masks to be provided with an electrical potential for the modulation of the plasma beam.

### REFERENCE NUMBER LIST

1 High-frequency plasma beam source
2 Housing
3 Plasma chamber
4 Extraction grid
5 Magnet
6 Gas supply
7 Coating chamber
8 High-frequency transmitter
9 Electrical connection
10 Substrates
11 Dome
12 Plasma beam
K₂ Dome's axis of symmetry
α Dome angle
R_{O} Radial distance source to axis of symmetry
Y_{O} Vertical distance source to center of symmetry

1-25. (canceled)

26. A high frequency plasma beam source comprising a plasma chamber for a plasma, electrical means for igniting and sustaining the plasma, an extraction grid at a high-frequency potential for extracting a plasma beam (I) from a plasma chamber as well as an outlet opening, preferably to a vacuum chamber, the extraction grid being arranged in the area of the outlet opening, wherein the plasma beam is made of a divergent shape by a specific interaction between the plasma and the extraction grid.

27. The high-frequency plasma beam source according to claim 26, wherein the divergency of the plasma beams (I) is achieved by a non-planar shape or a large mesh width in the extraction grid.

28. The high-frequency plasma beam source according to claim 26, wherein the achievement of a high homogeneity of the plasma current density on at least a portion of a curved, especially spherical surface that is to be irradiated, the plasma beam (I) is adapted to the shape of at least a portion of the surface area.

29. The high-frequency plasma beam source according to claim 26, wherein the extraction grid, as seen from the plasma chamber, is of concave shape

30. The high-frequency plasma beam source according to claim 26, wherein the extraction grid is of a non-uniform shape over at least a portion of its surface.

31. The high-frequency plasma beam source according to claim 26, wherein at least one mask disposed outside of the plasma chamber is provided.

32. The high-frequency plasma beam source according to claim 26, wherein the exit opening is covered with masks in areas.

33. The high-frequency plasma beam source according to claim 26, wherein the extraction grid has meshes with a mesh width that is less than the thickness of the space charge zone between extraction grid and the plasma in the plasma chamber.

34. The high-frequency plasma beam source according to claim 26, wherein the extraction grid has meshes with a mesh width that is at least as great as a thickness of the space charge zone between the extraction grid and the plasma in the plasma chamber.

35. The high-frequency plasma beam source according to claim 34, wherein the extraction grid has meshes with a mesh width that is no more than large enough for the plasma to remain substantially within the plasma space.

36. The high-frequency plasma beam source according to claim 26, wherein at lease one mask is provided with an electrical potential for the modulation of the plasma beam (I).

37. The high-frequency plasma beam source according to claim 26, wherein in a coating chamber, substantially opposite the exit opening, a curved surface with substrates.

38. The high frequency plasma bean source according to claim 37, wherein the curved surface is a dome.

39. The high-frequency plasma beam source according to claim 26, wherein an evaporating source is provided in addition to the high-frequency plasma beam source.

40. High-frequency plasma beam source according to claim 26, wherein the extraction grid is formed by a tungsten mesh with a wire thickness of about 0.02-3 mm.

41. High-frequency plasma beam source according to claim 26, wherein at least one magnet is provided for locking the plasma in the area of the plasma chamber.

42. A vacuum chamber comprising
a housing;
a high-frequency beam source; and
a surface to be irradiated, wherein the high-frequency plasma beam source is configured according to claim 26.

43. A vacuum chamber according to claim 42, wherein the surface to be irradiated is curved, preferably a dome and comprises one or more substrates.

44. A method for irradiating a surface with a plasma beam of a high-frequency plasma beam source, consisting of a divergent plasma beam is used and the high-frequency plasma beam source is configured according to claim 25.

45. A method according to claim 44, wherein the plasma beam has a beam characteristic with a divergence of no more than n=16, n being an exponent of a cosine distribution function.

46. The method of claim 45, wherein n=4.

47. A method according to at least claim 44, wherein the beam characteristic of the plasma beam is brought about by a controlled interaction between the plasma and an extraction grid.

48. A method according to claim 44, wherein a controlled interaction between an extracted plasma and at least one mask disposed outside of the plasma chamber is used.

49. A method according to claim 44, wherein for the achievement of a great homogeneity of the plasma beam density on at least a portion of a surface, the beam characteristic of the plasma beam is adapted to at least a portion of the irradiated surface.

50. A method according to claim 44, wherein a curved surface is provided.

51. A method according to claim 44, wherein the surface is coated by the irradiation of the surface.

52. A method according to claim 44, wherein the surface is cleaned or modified by the irradiation of the surface.

53. The method according to claim 50, wherein the curved surface is a dome.

54. The high frequency plasma beam source according to claim 29, wherein a portion of the surface of the extraction grid is a section of a mantle surface of a cylindrical body.
